(19) United States
(12) Patent Application Publication
(10) Pub. No.: US 2025/0194379 A1
(43) Pub. Date: Jun. 12, 2025

(54) DISPLAY DEVICE

(71) Applicant: Samsung Display Co., Ltd., Yongin-Si (KR)

(72) Inventor: Soo Ran PARK, Yongin-si (KR)

(21) Appl. No.: 18/786,609

(22) Filed: Jul. 29, 2024

(30) Foreign Application Priority Data
Dec. 6, 2023 (KR) 10-2023-0175641

(51) Int. Cl. H10K 59/80

(52) U.S. Cl. CPC H10K 59/873; H10K 59/8722

(57) ABSTRACT

The present disclosure relates to a display device, and more particularly, to a display device capable of minimizing peeling or damage of a light shielding layer. According to an embodiment of the disclosure, a display device comprising: a filler; a display panel on the filler; a window member on the display panel; a light shielding layer between the window member and the filler; and a buffer layer between the light shielding layer and the filler.

### CROSS-REFERENCE TO RELATED APPLICATION

This application claims priority from Korean Patent Application No. 10-2023-0175641 filed on Dec. 6, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, and more particularly, to a display device capable of minimizing peeling or damage of a light shielding layer.

### 2. Description of the Related Art

Various electronic devices that provide multimedia, such as televisions, mobile phones, navigation systems, computer monitors, and game consoles, are being developed. Electronic devices include a display panel that displays images. In particular, various portable electronic devices such as mobile phones and tablets have been developed recently. Additionally, display devices that work together with portable electronic devices are being developed.

### SUMMARY

Aspects of the present disclosure provide a display device capable of minimizing peeling or damage of a light shielding layer.

According to an embodiment of the disclosure, a display device comprising: a filler; a display panel on the filler; a window member on the display panel; a light shielding layer between the window member and the filler; and a buffer layer between the light shielding layer and the filler.

In an embodiment, the light shielding layer and the buffer layer may be formed of the same material.

In an embodiment, the light shielding layer and the buffer layer may have the same color.

In an embodiment, the buffer layer may contain black dye.

In an embodiment, the buffer layer may be in contact with the filler and the light shielding layer.

In an embodiment, a housing may be adjacent to the outer surface of the filler.

In an embodiment, the housing includes: a sidewall adjacent to the outer surface of the filler and the outer surface of the buffer layer; and a base plate extending from the sidewall.

In an embodiment, the sidewall may contact the outer surface of the light shielding layer and the outer surface of the window member.

In an embodiment, a first adhesive layer may be between the base plate and the filler.

In an embodiment, a second adhesive layer may be disposed between the display panel and the light shielding layer and between the display panel and the window member.

In an embodiment, the light shielding layer may be disposed between the second adhesive layer and the window member in addition to being disposed between the buffer layer and the window member.

In an embodiment, the light shielding layer may be in contact with the buffer layer and the second adhesive layer.

In an embodiment, the second adhesive layer may be surrounded by the buffer layer.

In an embodiment, a polarization plate may be between the display panel and the second adhesive layer.

In an embodiment, in plan view, the light shielding layer may surround a display area of the display panel.

In an embodiment, the light shielding layer may be disposed between the edge of the window member and the buffer layer.

According to an embodiment of the disclosure, a display device comprising: a filler; a display panel on the filler; a window member on the display panel; a light shielding layer between the window member and the filler; and a housing spaced apart from the filler, wherein at least a portion of the light shielding layer may cover a gap between the filler and the housing.

In an embodiment, the edge of the light shielding layer may be disposed on the gap.

In an embodiment, at least a portion of the light shielding layer overlapping the filler may be in contact with the filler.

In an embodiment, a first adhesive layer may be between the filler and a base plate of the housing.

In an embodiment, the gap may be defined by the housing, the first adhesive layer, the filler, and the light shielding layer.

In an embodiment, a sidewall of the housing may be adjacent to the outer surface of the first adhesive layer and the outer surface of the filler.

In an embodiment, a sidewall of the housing may be adjacent to the outer surface of the first adhesive layer, the outer surface of the filler, the outer surface of the light shielding layer, and the outer surface of the window member.

In an embodiment, the sidewall of the housing may be spaced apart from the outer surface of the first adhesive layer and the outer surface of the filler, and the sidewall of the housing may be in contact with the outer surface of the light shielding layer and the outer surface of the window member.

In an embodiment, at least a portion of a sidewall of the housing may be in contact with the lower surface of the light shielding layer.

In an embodiment, at least a portion of the sidewall of the housing may be in contact with the outer surface of the light shielding layer.

According to an embodiment of the disclosure, a display device comprising: a filler; a display panel on the filler; a window member on the display panel; and a light shielding layer between the window member and the filler, wherein the filler has a cure rate of 90%.

In an embodiment, the thermal expansion coefficient of the light shielding layer and the thermal expansion coefficient of the filler are the same.

In an embodiment, a difference between the thermal expansion coefficient of the light shielding layer and the thermal expansion coefficient of the filler may be no more than 10%.

In an embodiment, the filler and the light shielding layer are formed of the same material.

In the display device according to the present disclosure, peeling or damage of a light shielding layer may be minimized. Accordingly, even when a filler is deformed by heat, the image quality of a display device may not deteriorate.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view of a display device according to one embodiment;

FIG. 2 is a block diagram of a watch assembly of FIG. 1;

FIG. 3 is a plan view of a display device according to one embodiment;

FIG. 4 is a cross-sectional view of a display device according to one embodiment taken along line I-I′ of FIG. 3;

FIG. 5 is a cross-sectional view in respect to a display device according to another embodiment taken along line I-I′ of FIG. 3;

FIG. 6 is a cross-sectional view in respect to a display device according to still another embodiment taken along line I-I′ of FIG. 3;

FIG. 7 is a cross-sectional view in respect to a display device according to still another embodiment taken along line I-I′ of FIG. 3;

FIG. 8 is a cross-sectional view in respect to a display device according to still another embodiment taken along line I-I′ of FIG. 3;

FIG. 9 is a cross-sectional view in respect to a display device according to still another embodiment taken along line I-I′ of FIG. 3;

FIG. 10 is a cross-sectional view in respect to a display device according to still another embodiment taken along line I-I′ of FIG. 3;

FIGS. 11 to 15 are cross-sectional views illustrating structures of a light emitting element according to one embodiment;

FIG. 16 is a cross-sectional view illustrating an example of an organic light emitting diode of FIG. 14;

FIG. 17 is a cross-sectional view illustrating an example of an organic light emitting diode of FIG. 15;

FIG. 18 is a-sectional view illustrating a structure of a pixel of a display device according to one embodiment;

FIG. 19 is a plan view of a filler of a display device according to one embodiment; and

FIG. 20 is an enlarged view of portion A of FIG. 19.

### DETAILED DESCRIPTION OF THE EMBODIMENTS

The present invention will now be described more fully hereinafter with reference to the accompanying drawings, in which preferred embodiments are shown. This disclosure may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although ordinal terms “first”, “second”, etc. may be used herein to describe various elements, these elements should not be limited to any order or priority by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or wholly. As will be clearly appreciated by those skilled in the art, technically various interactions and operations are possible. Various embodiments can be practiced individually or in combination.

Hereinafter, specific exemplary embodiments will be described with reference to the accompanying drawings.

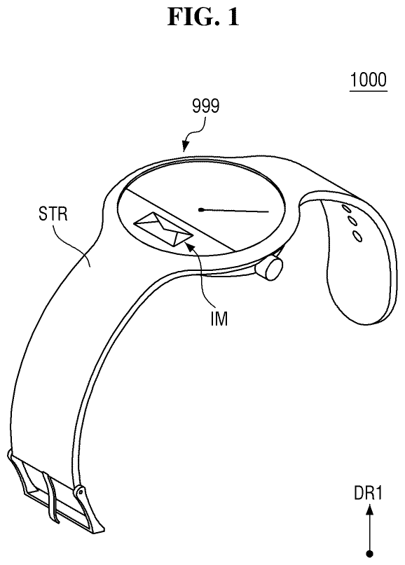

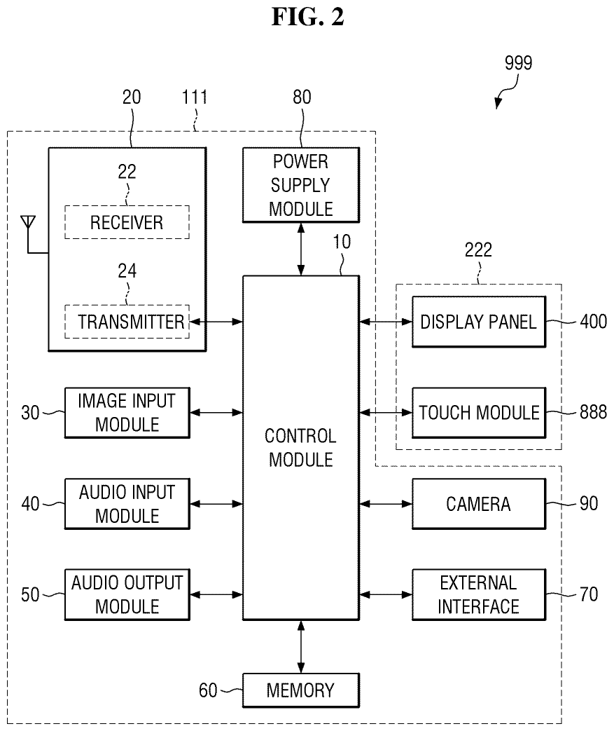

FIG. 1 is a perspective view of a display device according to one embodiment. FIG. 2 is a block diagram of a watch assembly of FIG. 1. Hereinafter, a display device according to one embodiment will be described referring to FIGS. 1 and 2.

Referring to FIG. 1, a display device 1000 according to one embodiment may be a watch. In addition, the display device according to one embodiment may not only be a watch but may be any device capable of displaying an image such as mobile phones, tablets, monitors, head-mount display devices or televisions.

The display device 1000 as a watch may include a watch assembly 999 and a strap STR. The watch assembly 999 may display an image IM having a predetermined information in a first direction DR1. Herein, the first direction DR1 may be indicated as a vertical direction or a thickness direction. For example, the image IM may display not only an image embodying an analog clock, such as clock hands indicating the current time, but also an icon of an application running on an application processor (not shown) or an execution screen of the application.

The watch assembly 999 may be detachably combined with the strap STR. A user may wear a strap STR on his or her wrist to use the display device 1000 (e.g., an electronic watch) on the wrist. The strap STR is not limited to the purpose of being worn on the user's wrist. The strap STR may be modified to be worn on other body parts such as the user's arm or around the neck, and can be replaced with a watch cradle for mounting the watch assembly 999 on another electronic device.

As shown in FIG. 2, the watch assembly 999 may include a display module 222 and an electronic module 111. The display module 222 may include a display panel 400 and a touch module 888. In one embodiment, the touch module 888 may be omitted. The touch module 888 may be integrated into the display module 222 or may be replaced with a keypad or the like.

The display module 222 may generate the image IM shown in FIG. 1. The display module 222 may include an organic light emitting display panel, a liquid crystal display panel, an electrophoretic display panel, and the like. The touch module 888 may detect external input. External input may be a touch or a hover by an external object such as the user's finger or a stylus pen. The type of the touch module 888 is not limited, and may be a capacitive touch module, a sound wave touch module, or an optical touch module.

The electronic module 111 may include various functional modules for operating the watch assembly 999. The electronic module 111 may include at least one of a control module 10, a wireless communication module 20, an image input module 30, an audio input module 40, an audio output module 50, a memory 60, an external interface 70, a power supply module 80, and a camera module 90. The modules may be mounted on a printing circuit substrate and be electrically connected to each other through a flexible circuit substrate.

The control module 10 may control the overall operation of the display device 1000 and process data. For example, the control module 10 may activate or deactivate the display module 222 and output input image data to the display module 222. The control module 10 activates or deactivates the touch module 888 and controls the display module 222, the image input module 30, the audio input module 40, and audio output module 50 and the like based on the touch signal received from the touch module 888.

The wireless communication module 20 may transmit/receive wireless signals to and from other terminals using a Bluetooth or Wi-Fi line. The wireless communication module 20 may transmit/receive audio signals using a general communication line. The wireless communication module 20 may include a transmitter 24 that modulates and transmits a signal to be transmitted, and a receiver 22 that demodulates the received signal.

The image input module 30 may process the input image data and convert the input image data into an image data that can be displayed on the display module 222. The audio input module 40 may receive an external audio signal through a microphone in a recording mode, voice recognition mode, or the like and convert the audio signal into electrical audio data. The audio output module 50 may convert the audio data received from the wireless communication module 20 or the audio data stored in the memory 60 and output the audio data to the outside.

The external interface 70 may serve as an interface connected to an external charger, a wired/wireless data port, a card socket (e.g., memory card, SIM/UIM card), or the like. The power supply module 80 may supply power required for the overall operation of the watch assembly 999.

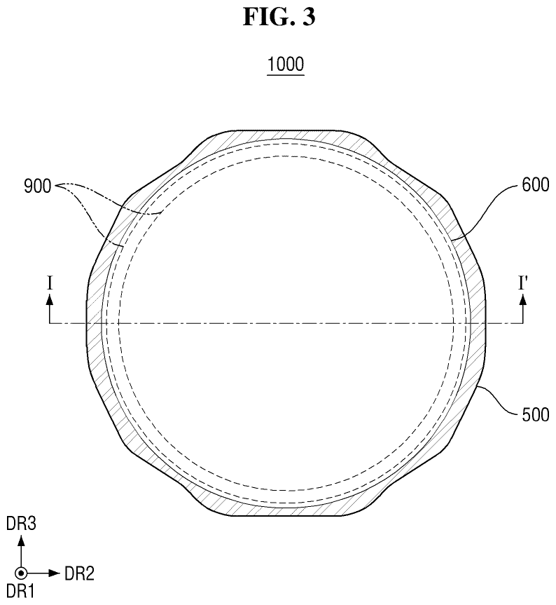

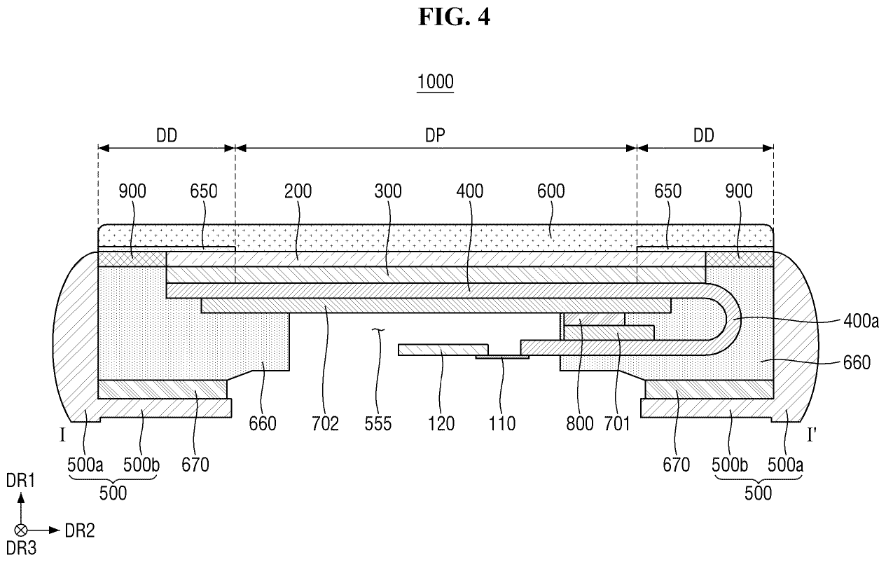

FIG. 3 is a plan view of a display device according to one embodiment, and FIG. 4 is a cross-sectional view of a display device according to one embodiment taken along line I-I′ of FIG. 3. Referring to FIG. 3, a surface of a part enclosed by the housing 500 that is closest to the housing 500 is herein referred to as an “outer surface.”

As illustrated in FIGS. 3 and 4, the display device according to one embodiment may include a display panel 400, a window member 600, a housing 500 (or a set bracket), a first support plate 701, a second support plate 702, a spacer 800, a polarization plate 300, a light shielding layer 650, a filler 660, a first adhesive layer 670, a second adhesive layer 200, and a buffer layer 900.

The housing 500 may include an accommodating space 555 that can accommodate the display panel 400, a first circuit board 110, a second circuit board 120, the first support plate 701, the second support plate 702, the spacer 800, the polarization plate 300, the first adhesive layer 670, the second adhesive layer 200, the buffer layer 900, and the filler 660. In other words, the housing 500 may define the accommodating space 555 described above. In plan view, the housing may have a shape of a closed curve shape surrounding the display panel 400, the first circuit board 110, the second circuit board 120, the first support plate 701, the second support plate 702, the spacer 800, the polarization plate 300, the first adhesive layer 670, the second adhesive layer 200, the buffer layer 900, and the filler 660. For example, in plan view, the housing 500 may have a ring shape defining the accommodating space 555 described above.

The housing 500 may include a sidewall 500a and a base plate 500b.

In plan view, the sidewall 500a may have a closed curve shape defining the accommodating space 555 described above. In addition, as illustrated in FIG. 4, the sidewall 500a may be disposed adjacent to the first adhesive layer 670, the filler 660, and the buffer layer 900. For example, the sidewall 500a may be adjacent to the outer surface of the first adhesive layer 670, the outer surface of the filler 660, and the outer surface of the buffer layer 900 in a second direction DR2. The sidewall 500a may be in contact with the outer surface of the first adhesive layer 670, the outer surface of the filler 660, and the outer surface of the buffer layer 900. The sidewall 500a may extend along the first direction DR1.

The base plate 500b may extend from the sidewall 500a toward the accommodating space 555. For example, the base plate 500b may extend from the inner side of the sidewall 500a toward the center of the accommodating space 555 in the second direction DR2, or the opposite direction of the second direction DR2 (hereinafter, a second reverse direction), or a third direction DR3, or the opposite direction of third direction DR3 (hereinafter, a third reverse direction). Here, the base plate 500b may extend from the lower portion of the inner side of the sidewall 500a. In plan view, the base plate 500b may have a closed curve shape with an open center.

The first adhesive layer 670 may be disposed on the base plate 500b of the housing 500. For example, the first adhesive layer 670 may be a pressure sensitive adhesive.

The filler 660 may be disposed on the first adhesive layer 670. The base plate 500b and the filler 660 may be adhered to each other by the first adhesive layer 670. In plan view, the filler 660 may have a closed curve shape surrounding the display panel 400, the first support plate 701, the spacer 800, the second support plate 702, the polarization plate 300, the first circuit board 110, and the second circuit board 120. The filler 660 may include resin. For example, the filler 660 may be formed with resin as a raw material in an insert molding method. The filler 660 may be made of a thermosetting resin containing a thermal polymerization initiator that initiates a curing reaction by heat. In accordance with one embodiment, the filler 660 may be made of a photo-curable resin containing a photopolymerization initiator that is crosslinked and cured by light such as ultraviolet rays, and infrared rays.

The second support plate 702, the display panel 400, the polarization plate 300, the second adhesive layer 200, and the buffer layer 900 may be disposed on the filler 660 along the first direction DR1.

The display panel 400 may display an image. For example, the display panel 400 may display an image in the first direction DR1. The display panel 400 may include a plurality of pixels providing light for displaying an image. The pixel may include a light emitting element. The display panel 400 may be disposed on the second support plate 702. A portion of the display panel 400 may be disposed inside the filler 660. For example, the display panel 400 may be a flexible display panel 400 that can be bent, and in this case, a bending portion 400a of the display panel 400 may be disposed inside the filler 660. One side of the display panel 400 may extend from the inside of the filler 660 to the outside and be disposed outside the filler 660. The first circuit board 110 may be connected to one side of the display panel 400. In addition, the second circuit board 120 may be connected to the first circuit board 110.

The first circuit board 110 may physically and electrically connect the display panel 400 and the second circuit board 120. For example, one end of the first circuit board 110 may be physically and electrically connected to a pad area of the display panel 400, and the other end of the first circuit board 110 may be physically and electrically connected to a pad area of the second circuit board 120. The one end of the first circuit board 110 may be connected to a pad electrode disposed in the pad area of the display panel 400 through a first conductive adhesive member. The other end of the first circuit board 110 may be connected to the second circuit board 120 through a second conductive adhesive member. For example, the other end of the first circuit board 110 may be connected to the second circuit board 120 through a second conductive adhesive member. For example, each of the first conductive adhesive member and the second conductive adhesive member may be an anisotropic conductive film (ACF).

For example, the first circuit board 110 may be a flexible printed circuit board, a printed circuit board, or a flexible film such as a chip on film.

For example, the second circuit board 120 may be a flexible printed circuit board, a printed circuit board, or a flexible film such as a chip on film. A touch driver and a power supplier may be mounted on the second circuit board 120. Circuit components (e.g., at least one of the touch driver and the power supplier) of the second circuit board 120 may be electrically connected to the display panel 400 through the second circuit board 120 and the first circuit board 110.

In addition, the first support plate 701 and the spacer 800 may be disposed inside the filler 660. For example, the first support plate 701 and the spacer 800 may be disposed between the display panel 400 and the second support plate 702 inside the filler 660. Here, the first support plate 701 may be disposed between the display panel 400 and the second support plate 702, and the spacer 800 may be disposed between the first support plate 701 and the second support plate 702.

The first support plate 701 may support the display panel 400. The first support plate 701 may be disposed on the inner surface of a portion of the display panel 400 connected to the first circuit board 110.

The second support plate 702 may support the display panel 400. The second support plate 702 may be disposed on the inner surface of a portion of the display panel 400 that is adjacent to the polarization plate 300.

The spacer 800 may be disposed between the first support plate 701 and the second support plate 702. The first support plate 701 and the second support plate 702 may be spaced apart by a predetermined distance by the spacer 800.

The polarization plate 300 may be disposed on the display panel 400. For example, the polarization plate 300 may include a linear polarization layer and at least one retardation layer. The linear polarization layer may be an optical layer that linearly polarizes light provided from the outside in one direction. The retardation layer may be a λ/2 retardation layer and a λ/4 retardation layer. The polarization plate 300 may function to reduce reflection caused by external light.

The second adhesive layer 200 may be disposed on the polarization plate 300. For example, the second adhesive layer 200 may include a pressure sensitive adhesive such as an optically clear resin (OCR) or an optically clear adhesive (OCA).

The buffer layer 900 may be disposed on the upper side of the edge of the filler 660. The buffer layer 900 may be disposed on the same layer as the second adhesive layer 200 described above. For example, the buffer layer 900 may be disposed in an area surrounded by the filler 660, the sidewall 550a, the second adhesive layer 200, and the light shielding layer 650. The buffer layer 900 may be in contact with the filler 660, the sidewall 550a, the second adhesive layer 200, and the light shielding layer 650. In plan view, the buffer layer 900 may have a closed curve shape surrounding the second adhesive layer 200. For example, the buffer layer 900 may have a ring shape surrounding the second adhesive layer 200 (see FIG. 3).

For example, the buffer layer 900 may include a pressure sensitive adhesive or a waterproof tape. For example, the buffer layer 900 may be made of the same material as the first adhesive layer 670.

According to one embodiment, the thermal expansion coefficient (or thermal mechanical coefficient) of the buffer layer 900 and the thermal expansion coefficient (or thermal mechanical coefficient) of the light shielding layer 650 may be the same. In other words, the buffer layer 900 may be manufactured with the same material as the light shielding layer 650. For example, the buffer layer 900 may be formed of an organic black pigment or an inorganic black pigment described above.

According to one embodiment, the difference between the thermal expansion coefficient (or thermal mechanical coefficient) of the buffer layer 900 and the thermal expansion coefficient (or thermal mechanical coefficient) of the light shielding layer 650 may be no larger than 10%. For example, the thermal expansion coefficient of the light shielding layer 650 may be greater by 10% or smaller by 10% than the thermal expansion coefficient of the buffer layer 900.

In one embodiment, in order to improve the light shielding effect in a dead space area DD, the buffer layer 900 may have the same color (e.g., black) as the light shielding layer 650. According to one embodiment for this purpose, the buffer layer 900 may include black dye.

The buffer layer 900 may reduce stress (e.g., force) of the light shielding layer 650 due to deformation of the filler 660. For example, the filler 660 can be deformed (expanded or contracted) by heat, and when the filler 660 and the light shielding layer 650 are in contact (or in direct contact), stress of the light shielding layer 650 corresponding to the deformation of the filler 660 may increase. At this time, since the adhesive force between the light shielding layer 650 and the window member 600 is weaker than the stress, the light shielding layer 650 may be separated (or peeled) from the window member 600 due to stress or damage such as cracks in the light shielding layer 650 may occur. Then, light may not be shielded properly from the dead space area DD of the display device 1000, thereby deteriorating the image quality. The buffer layer 900 described above may prevent the light shielding layer 650 from being peeled off or damaged by buffering the stress caused by deformation of the filler 660 from being directly transmitted to the light shielding layer 650.

The light shielding layer 650 may be disposed on the buffer layer 900 and the edge of the second adhesive layer 200. The light shielding layer 650 may be disposed between the buffer layer 900 and the window member 600, and between the second adhesive layer 200 and the window member 600. The light shielding layer 650 may be in contact with the second adhesive layer 200, the buffer layer 900, and the window member 600. The filler 660 and the light shielding layer 650 may be adhered to each other by the buffer layer 900. The light shielding layer 650 may define a display area DP of the display panel 400. In plan view, the light shielding layer 650 may be disposed in the dead space area DD of the display device 1000 and surround the display area DP. In plan view, the light shielding layer 650 may have a closed curve shape surrounding the display area DP.

The light shielding layer 650 may include a light absorbing material (or an opaque material). For example, the light shielding layer 650 may include an inorganic black pigment or an organic black pigment. The inorganic black pigment may be carbon black, and the organic black pigment may include at least one of lactam black, perylene black, or aniline black, but they are not limited thereto. For example, the light shielding layer 650 may be made of a material containing any one of colors other than black. According to an embodiment, the light shielding layer 650 may include an opaque white material. In addition, in one embodiment, the light shielding layer 650 may include a carbon-based light shielding material such as the carbon black described above, a dye, a pigment, or a combination thereof. The light shielding material may be dispersed within a binder polymer. For example, the light shielding layer 650 may be formed using a black matrix composition well known in the display field.

The window member 600 may be disposed on the light shielding layer 650 and the second adhesive layer 200 in the display area DP. The window member 600 may be combined with the housing 500 to define the accommodating space 555 described above. The window member 600 may be made of a transparent material that can transmit light (e.g., image) from the display panel 400. For example, the window member 600 may include rigid glass or a flexible transparent polymer. The light shielding layer 650 may be adhered to the inner surface of the window member 600 along the edge of the window member 600. The window member 600 and the polarization plate 300 may be adhered to each other by the second adhesive layer 200.

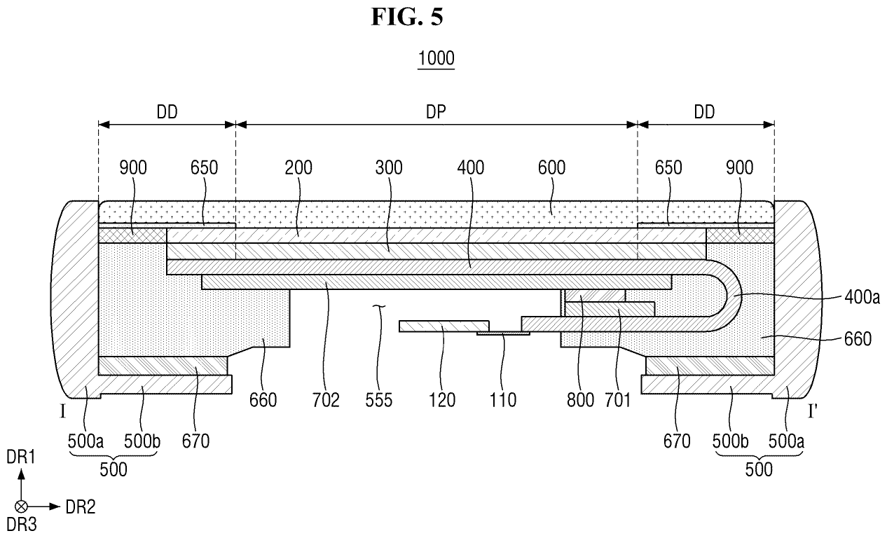

FIG. 5 is a cross-sectional view in respect to a display device 1000 according to another embodiment taken along line I-I′ of FIG. 3.

The display device 1000 of FIG. 5 is different from the display device 1000 of FIG. 4 described above in the shape of the sidewall 500a of the housing 500, and the difference will be mainly described as below.

The sidewall 500a of the housing 500 of FIG. 5 may be disposed adjacent to the first adhesive layer 670, the filler 660, the buffer layer 900, the light shielding layer 650, and the window member 600. For example, the sidewall 500a may be adjacent to the outer surface of the first adhesive layer 670, the outer surface of the filler 660, the outer surface of the buffer layer 900, the outer surface of the light shielding layer 650, and the outer surface of the window member 600. The sidewall 500a may be in contact with the outer surface of the first adhesive layer 670, the outer surface of the filler 660, the outer surface of the buffer layer 900, the outer surface of the light shielding layer 650 and the outer surface of the window member 600. The sidewall 500a may extend along the first direction DR1. In other words, the sidewall 500a of FIG. 5 may extend in the first direction DR1 to increase the contact area with the outer surface of the light shielding layer 650 and the outer surface of the window member 600.

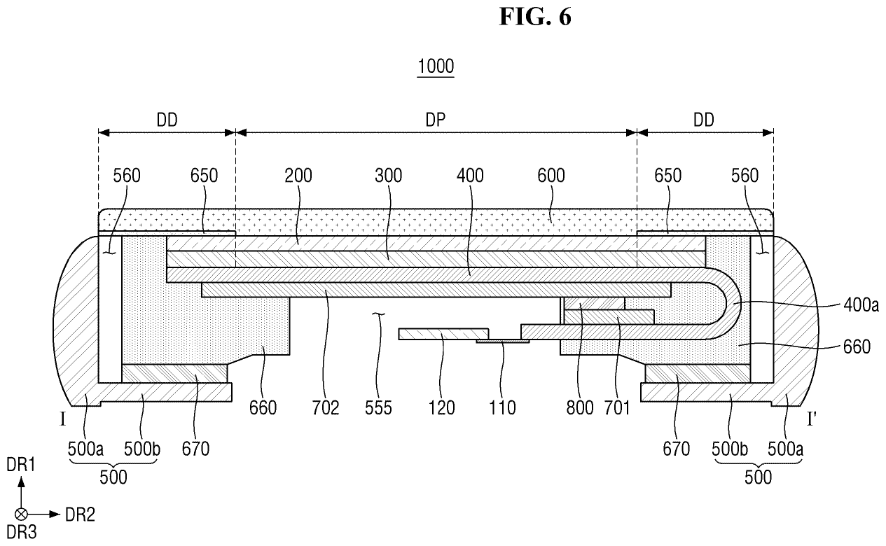

FIG. 6 is a cross-sectional view of a display device 1000 according to another embodiment, taken along a line that corresponds to the line I-I′ shown in FIG. 3.

The display device 1000 of FIG. 6 is different from the display device 1000 of FIG. 4 described above in the presence of a gap 560 (which affects the shape of the filler 660 and the first adhesive layer 670) and the absence of the buffer layer 900, and the difference will be described in detail below.

As illustrated in FIG. 6, the first adhesive layer 670 and the sidewall 500a of the housing 500 may be disposed to be spaced apart from each other in the second direction DR2. In addition, the filler 660 and the sidewall 500a of the housing 500 may be disposed to be spaced apart from each other in the second direction DR2. Accordingly, a gap 560 may exist between the first adhesive layer 670 and the sidewall 500a and between the filler 660 and the sidewall 500a. For example, the gap 560 described above may be defined as an area (or a space) surrounded by the sidewall 500a, the first adhesive layer 670, the filler 660, and the light shielding layer 650. In plan view, the gap 560 may have a closed curve shape surrounding the first adhesive layer 670 and the filler 660.

At least a portion of the light shielding layer 650 may not be in contact with the filler 660 due to the gap 560 described above. For example, the edge of the light shielding layer 650 may not contact the filler 660. In other words, the light shielding layer 650 may be in contact with the filler 660 except for the edges of the light shielding layer 650. For example, at least a portion of the light shielding layer 650 overlapping the filler 660 may be in contact with the upper surface of the filler 660. Accordingly, the edge of the light shielding layer 650 may be adjacent to the base plate 500b of the housing 500.

In addition, the first adhesive layer 670 and the filler 660 may not be in contact with the sidewall 500a due to the gap 560 described above.

According to the display device 1000 of FIG. 6, the edge of the light shielding layer 650 may be disposed on the gap 560 without contacting the filler 660, thereby preventing the light shielding layer 650 from being separated (or peeled) from the window member 600. For example, because the contact area between the filler 660 and the light shielding layer 650 is reduced by the gap 560, even if the filler 660 is deformed by heat, the stress (e.g., force) applied to the light shielding layer 650 may not significantly increase. Accordingly, peeling or damage to the light shielding layer 650 can be minimized.

Meanwhile, the display device 1000 of FIG. 6 does not include the buffer layer 900 shown in FIG. 4. Accordingly, the light shielding layer 650 of FIG. 6 may directly contact the filler 660 and the second adhesive layer 200. At this time, the light shielding layer 650 of FIG. 6 may be in contact with the upper surface of the filler 660 and the upper surface of the second adhesive layer 200. However, as described above, the edge of the light shielding layer 650 in FIG. 6 may be disposed on the gap 560.

In addition, in plan view, the filler 660 in FIG. 6 may have a closed curve shape surrounding the display panel 400, the first support plate 701, the spacer 800, the second support plate 702, the polarization plate 300, the second adhesive layer 200, the first circuit board 110, and the second circuit board 120.

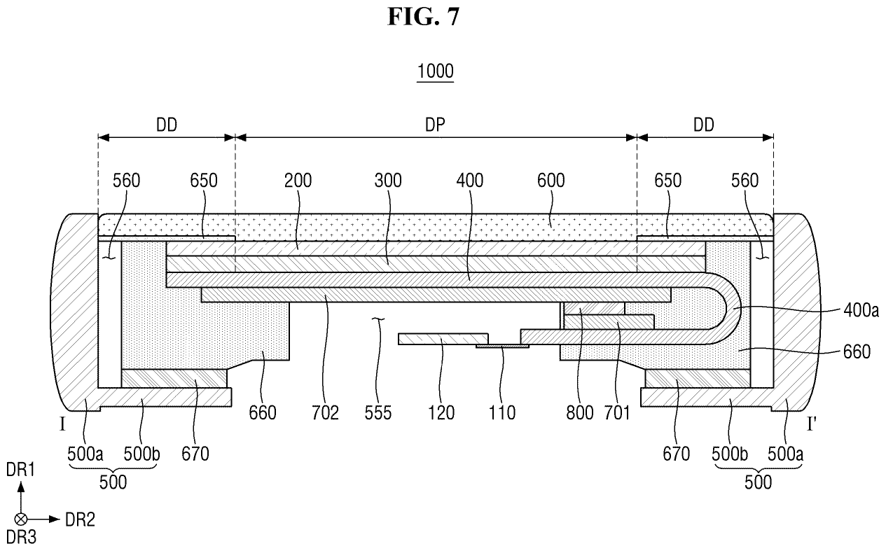

FIG. 7 is a cross-sectional view of a display device 1000 according to another embodiment taken along a line that corresponds to the line I-I′ of FIG. 3.

The display device 1000 of FIG. 7 is different from the display device 1000 of FIG. 6 described above in the shape of the sidewall 500a of the housing 500, and the difference will be described in detail below.

The sidewall 500a of the housing 500 of FIG. 7 may be disposed adjacent to the first adhesive layer 670, the filler 660, the light shielding layer 650, and the window member 600. For example, the sidewall 500a may be adjacent to the outer surface of the first adhesive layer 670, the outer surface of the filler 660, the outer surface of the light shielding layer 650, and the outer surface of the window member 600 in the second direction DR2. In other words, the sidewall 500a may further extend in the first direction DR1 to be adjacent to the outer surface of the light shielding layer 650 and the outer surface of the window member 600. At this time, the sidewall 500a may be in contact with the outer surface of the light shielding layer 650 and the outer surface of the window member 600. In other words, the sidewall 500a may not be in contact with the first adhesive layer 670 and the filler 660, and be in contact with the outer surface of the light shielding layer 650 and the outer surface of the window member 600.

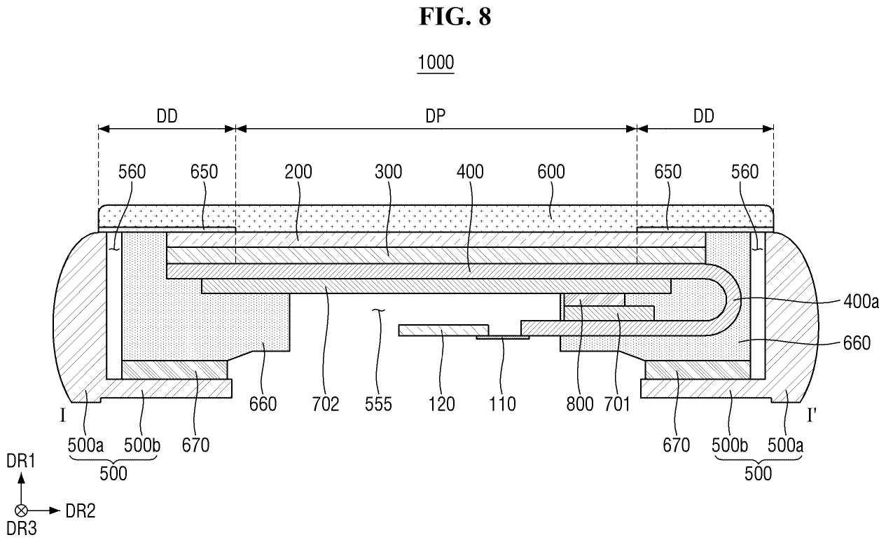

FIG. 8 is a cross-sectional view of a display device 1000 according to another embodiment taken along line I-I′ of FIG. 3.

The display device 1000 of FIG. 8 is different from the display device 1000 of FIG. 6 described above in the shape of the sidewall 500a of the housing 500. The following description will focus on the difference.

As illustrated in FIG. 8, at least a portion of a sidewall 500a may be in contact with the lower surface of the light shielding layer 650. For example, at least a portion of the edge of the light shielding layer 650 may be supported by the sidewall 500a.

A gap 560 of FIG. 8 may be smaller than the gap 560 of FIG. 6 described above.

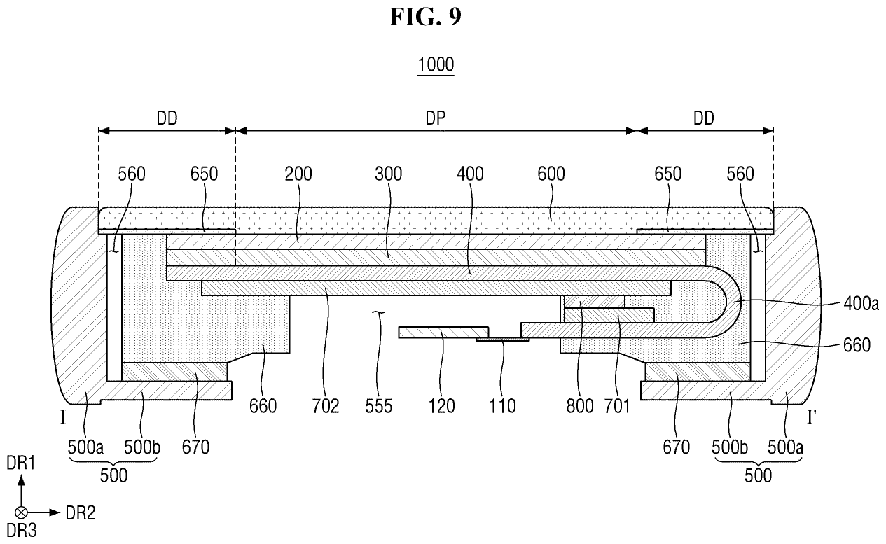

FIG. 9 is a cross-sectional view of a display device 1000 according to another embodiment taken along line I-I′ of FIG. 3.

The display device 1000 of FIG. 9 is different from the display device 1000 of FIG. 8 described above in the shape of the sidewall 500a of the housing 500. The description below will focus on this difference.

As illustrated in FIG. 9, the sidewall 500a may further extend in the first direction DR1 to the same height as the outer surface of the light shielding layer 650 and the outer surface of the window member 600. At this time, the sidewall 500a may be in contact with the outer surface of the light shielding layer 650 and the outer surface of the window member 600.

According to the display device 1000 of FIG. 9, a sidewall 500a may be in contact with the outer surface and the lower surface of the edge of the light shielding layer 650.

A gap 560 of FIG. 9 may be smaller than the gap 560 of FIG. 6.

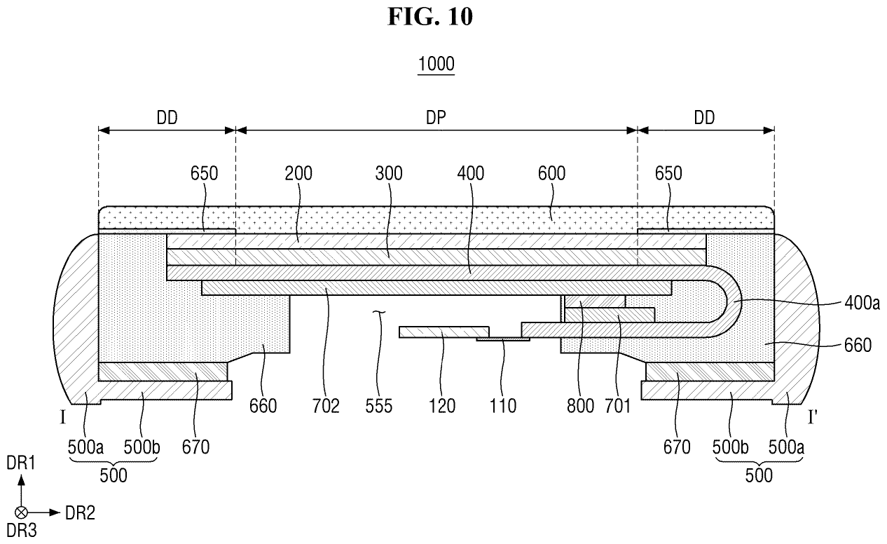

FIG. 10 is a cross-sectional view in respect to a display device 1000 according to still another embodiment taken along line I-I′ of FIG. 3.

The display device 1000 of FIG. 10 is different from the display device 1000 of FIG. 4 described above in that there is no buffer layer 900. The following description will focus on this difference.

As illustrated in FIG. 10, the light shielding layer 650 may be directly disposed on the filler 660. For example, the light shielding layer 650 may be in contact (or in direct contact) with the filler 660.

In plan view, the filler 660 of FIG. 10 may have a closed curve shape surrounding the display panel 400, the first support plate 701, the spacer 800, the second support plate 702, the polarization plate 300, the second adhesive layer 200, the first circuit board 110, and the second circuit board 120.

The filler 660 of FIG. 10 may have a cure rate of, for example, 90% or more. In another embodiment, the filler 660 of FIG. 10 may have a cure rate of 80% or more.

When the filler 660 has a curing rate of 90% (or 80%) or more, the degree of deformation of the filler 660 due to external heat may be reduced. Accordingly, since the stress (e.g., force) applied to the light shielding layer 650 in direct contact with the filler 660 is reduced, the problem in which the light shielding layer 650 is separated from the window member 600 due to the stress can be resolved. In other words, when a cure rate of the filler 660 is sufficiently high, the peeling phenomenon of the light shielding layer 650 can be minimized even when the light shielding layer 650 is in direct contact with the filler 660.

According to one embodiment, the thermal expansion coefficient (or thermal mechanical coefficient) of the light shielding layer 650 of FIG. 10 and the thermal expansion coefficient (or thermal mechanical coefficient) of the filler 660 may be the same. In other words, the filler 660 may be made of the same material as the light shielding layer 650. For example, the filler 660 may be formed of an organic black pigment or an inorganic black pigment described above. In this case, since the light shielding layer 650 is also deformed (e.g., expanded or contracted) to the same size as the filler 660 when the filler 660 is deformed (e.g., expanded or contracted) by heat, stress (e.g., force) applied to the light shielding layer 650 may be reduced. Accordingly, even when the light shielding layer 650 is in direct contact with the filler 660, peeling phenomenon of the light shielding layer 650 can be minimized.

According to one embodiment, the difference between the thermal expansion coefficient (or thermal mechanical coefficient) of the light shielding layer 650 of FIG. 10 and the thermal expansion coefficient (or thermal mechanical coefficient) of the filler 660 may be as much as 10%. For example, the thermal expansion coefficient of the light shielding layer 650 may be greater by up to 10% or smaller by up to 10% than the thermal expansion coefficient of the filler 660. In this case, since the light shielding layer 650 is also deformed (e.g., expanded or contracted) to almost the same size as the filler 660 when the filler 660 is deformed (e.g., expanded or contracted) by heat, stress (e.g., force) applied to the light shielding layer 650 may be reduced. Accordingly, even when the light shielding layer 650 is in direct contact with the filler 660, peeling phenomenon of the light shielding layer 650 can be minimized.

Meanwhile, the light emitting element of the above-described pixel may have a tandem structure, which is explained with reference to FIGS. 11 to 18 as follows.

FIGS. 11 to 15 are cross-sectional views illustrating structures of a light emitting element according to one embodiment.

Referring to FIG. 11, a light emitting element (e.g., an organic light emitting diode) according to one embodiment may include a pixel electrode 201, a common electrode 205, and an intermediate layer 203 between the pixel electrode 201 and the common electrode 205 described above.

The pixel electrode 201 may include a light-transmitting conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 201 may include a reflective layer containing silver (Ag), magnesium (Mg), aluminum (Al), platinum (Pt), palladium (Pd), gold (Au), nickel (Ni), neodymium (Nd), iridium (Ir), chromium (Cr) or a compound thereof. For example, the pixel electrode 201 may have a three-layer structure of ITO/Ag/ITO.

The common electrode 205 may be disposed on the intermediate layer 203. The common electrode 205 may include a low work function metal, an alloy, an electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a semi-transmissive electrode, or a reflective electrode.

The intermediate layer 203 may include a high molecular material or a low molecular material that emits light of a predetermined color. In addition to various organic materials, the intermediate layer 203 may further include metal-containing compounds such as organometallic compounds, inorganic materials such as quantum dots, and the like.

In one embodiment, the intermediate layer 203 may include one light emitting layer and a first functional layer and a second functional layer respectively disposed below and above the one light emitting layer. The first functional layer may include, for example, a hole transport layer HTL or may include the hole transport layer and a hole injection layer HIL. The second functional layer is a component disposed on the light emitting layer and is optional. For example, the intermediate layer 203 may include or may not include the second functional layer. The second functional layer may include an electron transport layer ETL and/or an electron injection layer EIL.

In one embodiment, the intermediate layer 203 may include two or more emitting units that are sequentially stacked between the pixel electrode 201 and the common electrode 205, and a charge generation layer CGL disposed between the two emitting units. When the intermediate layer 203 includes an emitting unit and a charge generation layer, a light emitting element (e.g., an organic light emitting diode) may be a tandem light emitting element. A light emitting element (e.g., an organic light emitting diode) may improve color purity and luminous efficiency by having a stacked structure of a plurality of emitting units.

One emitting unit may include a light emitting layer and a first functional layer and a second functional layer respectively disposed below and above the light emitting layer. The charge generation layer CGL may include a negative charge generation layer and a positive charge generation layer. The luminous efficiency of an organic light emitting diode, which is a tandem light emitting element having a plurality of light emitting layers, may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

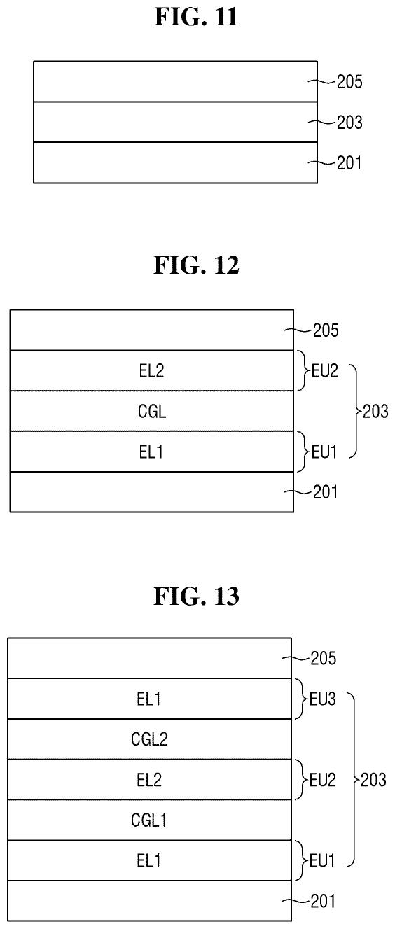

In one embodiment, as illustrated in FIG. 12, a light emitting element (e.g., an organic light emitting diode) may include a first emitting unit EU1 including a first light emitting layer EL1 and a second emitting unit EU2 including a second light emitting layer EL2 that are sequentially stacked. The charge generation layer CGL may be disposed between the first emitting unit EU1 and the second emitting unit EU2. For example, a light emitting element (e.g., an organic light emitting diode) may include the pixel electrode 201, the first light emitting layer EL1, the charge generation layer CGL, the second light emitting layer EL2, and the common electrode 205 that are sequentially stacked. The first functional layer and the second functional layer may be disposed on and under the first light emitting layer EL1, respectively. The first functional layer and the second functional layer may be included below and above the second light emitting layer EL2, respectively. The first light emitting layer EL1 may be a blue light emitting layer, and the second light emitting layer EL2 may be a yellow light emitting layer.

In one embodiment, as illustrated in FIG. 13, a light emitting element (e.g., an organic light emitting diode) may include the first emitting unit EU1 and a third emitting unit EU3 each including the first light emitting layer EL1, and the second emitting unit EU2 including the second light emitting layer EL2. A first charge generation layer CGL1 may be disposed between the first emitting unit EU1 and the second emitting unit EU2, and a second charge generation layer CGL2 may be disposed between the second emitting unit EU2 and the third emitting unit EU3. For example, a light emitting element (e.g., an organic light emitting diode) may include the pixel electrode 201, the first light emitting layer EL1, the first charge generation layer CGL1, the second light emitting layer EL2, the second charge generation layer CGL2, the first light emitting layer EL1, and the common electrode 205 that are sequentially stacked. The first functional layer and the second functional layer may be disposed on and under the first light emitting layer EL1, respectively. The first functional layer and the second functional layer may be disposed on and below the second light emitting layer EL2, respectively. The first light emitting layer EL1 may be a blue light emitting layer, and the second light emitting layer EL2 may be a yellow light emitting layer.

In one embodiment, in a light emitting element (e.g., an organic light emitting diode), the second emitting unit EU2 may further include a third light emitting layer EL3 and/or a fourth light emitting layer EL4 directly in contact with the second light emitting layer EL2 below and/or above the second light emitting layer EL2, in addition to the second light emitting layer EL2. Here, direct contact may mean that no other layer is disposed between the second light emitting layer EL2 and the third light emitting layer EL3 and/or between the second light emitting layer EL2 and the fourth light emitting layer EL4. The third light emitting layer EL3 may be a red light emitting layer, and the fourth light emitting layer EL4 may be a green light emitting layer.

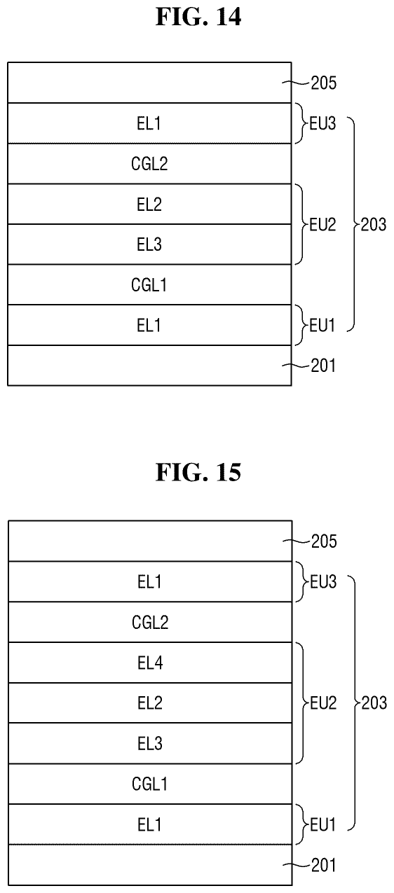

For example, as illustrated in FIG. 14, a light emitting element (e.g., an organic light emitting diode) may include the pixel electrode 201, the first light emitting layer EL1, the first charge generation layer CGL1, the third light emitting layer EL3, the second light emitting layer EL2, the second charge generation layer CGL2, the first light emitting layer EL1, and the common electrode 205 that are sequentially stacked. Alternatively, as illustrated in FIG. 15, a light emitting element (e.g., an organic light emitting diode) may include the pixel electrode 201, the first light emitting layer EL1, the first charge generation layer CGL1, the third light emitting layer EL3, the second light emitting layer EL2, the fourth light emitting layer EL4, the second charge generation layer CGL2, the first light emitting layer EL1, and the common electrode 205 that are sequentially stacked.

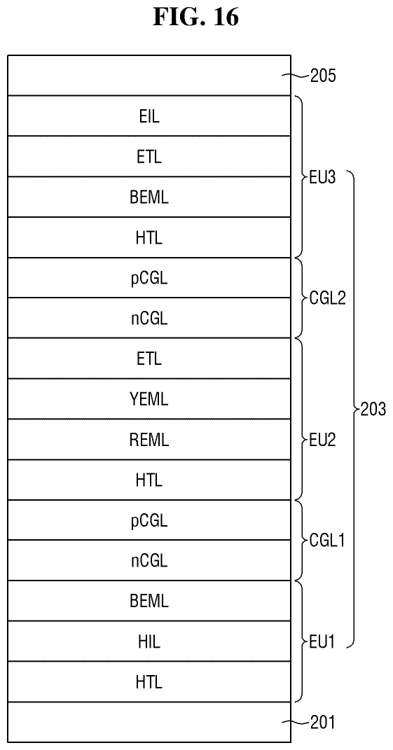

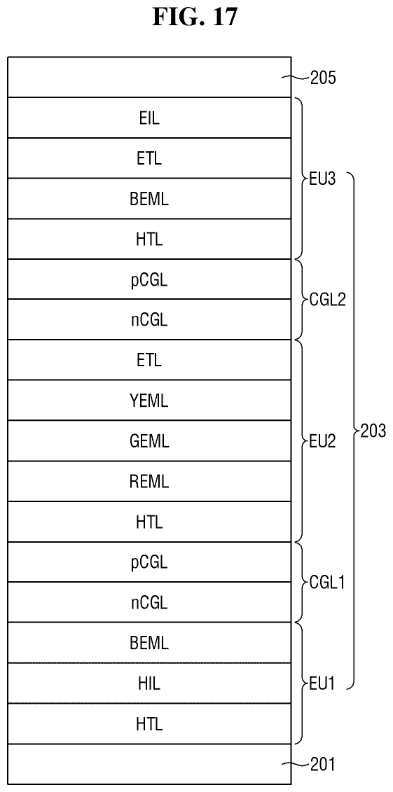

FIG. 16 is a cross-sectional view illustrating an example of the organic light emitting diode of FIG. 14, and FIG. 17 is a cross-sectional view illustrating an example of the organic light emitting diode of FIG. 15.

Referring to FIG. 16, a light emitting element (e.g., an organic light emitting diode) may include the first emitting unit EU1, the second emitting unit EU2, and the third emitting unit EU3 that are sequentially stacked. The first charge generation layer CGL1 may be disposed between the first emitting unit EU1 and the second emitting unit EU2, and the second charge generation layer CGL2 may be disposed between the second emitting unit EU2 and the third emitting unit EU3. The first charge generation layer CGL1 and the second charge generation layer CGL2 may include a negative charge generation layer nCGL and a positive charge generation layer pCGL, respectively.

The first emitting unit EU1 may include a blue light emitting layer BEML. The first emitting unit EU1 may further include the hole injection layer HIL and the hole transport layer HTL between the pixel electrode 201 and the blue light emitting layer BEML. In one embodiment, a p-doped layer may be further included between the hole injection layer HIL and the hole transport layer HTL. The P-doped layer may be formed by doping the hole injection layer HIL with a p-type doping material. In one embodiment, at least one of a blue light auxiliary layer, an electron blocking layer, or a buffer layer may be further included between the blue light emitting layer BEML and the hole transport layer HTL. The blue light auxiliary layer may increase light emission efficiency of the blue light emitting layer BEML. The blue light auxiliary layer may increase light emission efficiency of the blue light emitting layer BEML by adjusting hole charge balance. The electron blocking layer may prevent electron injection into the hole transport layer HTL. The buffer layer may compensate for a resonance distance according to a wavelength of light emitted from the light emitting layer.

The second emitting unit EU2 may include a yellow light emitting layer YEML and a red light emitting layer REML in direct contact with the yellow light emitting layer YEML below the yellow light emitting layer YEML. The second emitting unit EU2 may further include the hole transport layer HTL between the positive charge generation layer pCGL of the first charge generation layer CGL1 and the red light emitting layer REML, and may further include the electron transport layer ETL between the yellow light emitting layer YEML and the negative charge generation layer nCGL of the second charge generation layer CGL2.

The third emitting unit EU3 may include the blue light emitting layer BEML. The third emitting unit EU3 may further include the hole transport layer HTL between the positive charge generation layer pCGL of the second charge generation layer CGL2 and the blue light emitting layer BEML. The third emitting unit EU3 may further include the electron transport layer ETL and the electron injection layer EIL between the blue light emitting layer BEML and the common electrode 205. The electron transport layer ETL may have a single layer or a multilayer. In one embodiment, at least one of a blue light auxiliary layer, an electron blocking layer, or a buffer layer may be further included between the blue light emitting layer BEML and the hole transport layer HTL. At least one of a hole blocking layer or a buffer layer may be further included between the blue light emitting layer BEML and the electron transport layer ETL. The hole blocking layer may prevent hole injection into the electron transport layer ETL.

A light emitting element (e.g., an organic light emitting diode) illustrated in FIG. 17 is different from the light emitting element (e.g., an organic light emitting diode) illustrated in FIG. 15 in the stacked structure of the second emitting unit EU2, and other configurations are the same. Referring to FIG. 17, the second emitting unit EU2 may include the yellow light emitting layer YEML, the red light emitting layer REML directly in contact with the yellow light emitting layer YEML below the yellow light emitting layer YEML, and a green light emitting layer GEML directly in contact with the yellow light emitting layer YEML above the yellow light emitting layer YEML. The second emitting unit EU2 may further include the hole transport layer HTL between the positive charge generation layer pCGL of the first charge generation layer CGL1 and the red light emitting layer REML, and may further include the electron transport layer ETL between the green light emitting layer GEML and the negative charge generation layer nCGL of the second charge generation layer CGL2.

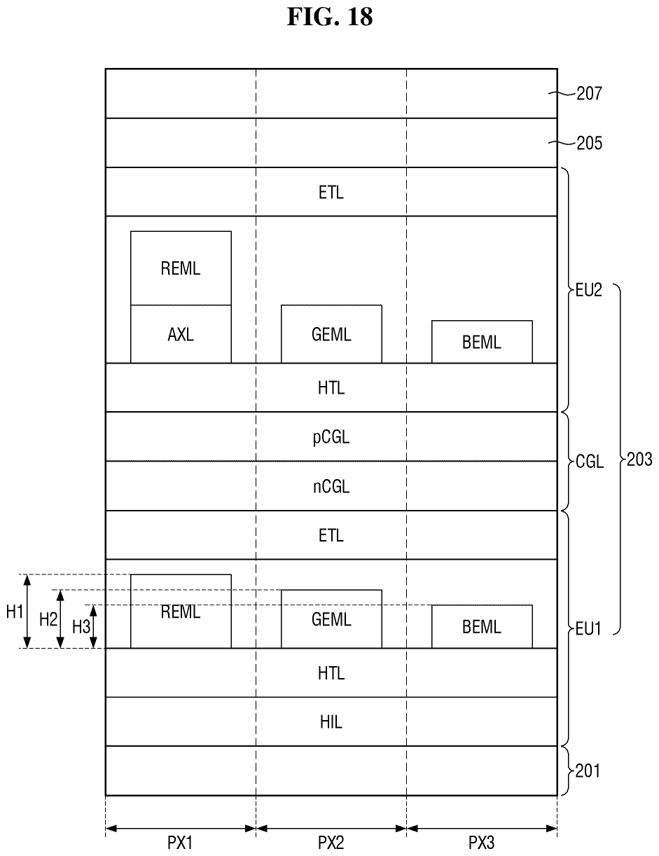

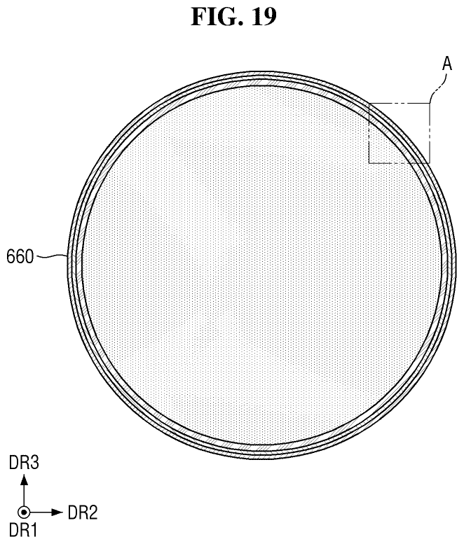

FIG. 18 is a cross-sectional view illustrating a structure of a pixel of a display device 1000 according to one embodiment.

Referring to FIG. 18, the display panel 400 of the display device 1000 may include a plurality of pixels. The plurality of pixels may include the first pixel PX1, the second pixel PX2, and the third pixel PX3. Each of the first pixel PX1, the second pixel PX2, and the third pixel PX3 may include the pixel electrode 201, the common electrode 205, and the intermediate layer 203. In one embodiment, the first pixel PX1 may be a red pixel, the second pixel PX2 may be a green pixel, and the third pixel PX3 may be a blue pixel.

The pixel electrode 201 may be independently provided in each of the first pixel PX1, the second pixel PX2, and the third pixel PX3.

The intermediate layer 203 of each of the first pixel PX1, the second pixel PX2, and the third pixel PX3 may include the first emitting unit EU1 and the second emitting unit EU2 that are sequentially stacked, and the charge generation layer CGL between the first emitting unit EU1 and the second emitting unit EU2. The charge generation layer CGL may include the negative charge generation layer nCGL and the positive charge generation layer pCGL. The charge generation layer CGL may be a common layer continuously formed in the first pixel PX1, the second pixel PX2, and the third pixel PX3.

The first emitting unit EU1 of the first pixel PX1 may include the hole injection layer HIL, the hole transport layer HTL, the red light emitting layer REML, and the electron transport layer ETL that are sequentially stacked on the pixel electrode 201. The first emitting unit EU1 of the second pixel PX2 may include the hole injection layer HIL, the hole transport layer HTL, the green light emitting layer GEML, and the electron transport layer ETL that are sequentially stacked on the pixel electrode 201. The first emitting unit EU1 of the third pixel PX3 may include the hole injection layer HIL, the hole transport layer HTL, the blue light emitting layer BEML, and the electron transport layer ETL that are sequentially stacked on the pixel electrode 201. Each of the hole injection layer HIL, the hole transport layer HTL, and the electron transport layer ETL of the first emitting unit EU1 may be a common layer continuously formed in the first pixel PX1, the second pixel PX2, and the third pixel PX3.

The second emitting unit EU2 of the first pixel PX1 may include the hole transport layer HTL, an auxiliary layer AXL, the red light emitting layer REML, and the electron transport layer ETL that are sequentially stacked on the charge generation layer CGL. The second emitting unit EU2 of the second pixel PX2 may include the hole transport layer HTL, the green light emitting layer GEML, and the electron transport layer ETL that are sequentially stacked on the charge generation layer CGL. The second emitting unit EU2 of the third pixel PX3 may include the hole transport layer HTL, the blue light emitting layer BEML, and the electron transport layer ETL that are sequentially stacked on the charge generation layer CGL. Each of the hole transport layer HTL and the electron transport layer ETL of the second emitting unit EU2 may be a common layer continuously formed in the first pixel PX1, the second pixel PX2, and the third pixel PX3. In one embodiment, at least one of a hole blocking layer or a buffer layer may be further included between the light emitting layer and the electron transport layer ETL in the second emitting unit EU2 of the first pixel PX1, the second pixel PX2, and the third pixel PX3.

A thickness H1 of the red light emitting layer REML, a thickness H2 of the green light emitting layer GEML, and a thickness H3 of the blue light emitting layer BEML may be determined according to the resonance distance. The auxiliary layer AXL may be a layer added to adjust the resonance distance, and may include a resonance auxiliary material. For example, the auxiliary layer AXL may include the same material as the hole transport layer HTL.

In FIG. 18, the auxiliary layer AXL may be disposed only in the first pixel PX1, but the embodiment of the present disclosure is not limited thereto. For example, the auxiliary layer AXL may be disposed in at least one of the first pixel PX1, the second pixel PX2, or the third pixel PX3 to adjust the resonance distance of each of the first pixel PX1, the second pixel PX2, and the third pixel PX3.

The display panel 400 of the display device 1000 may further include a capping layer 207 disposed outside the common electrode 205. The capping layer 207 may serve to improve luminous efficiency by the principle of constructive interference. Accordingly, the light extraction efficiency of a light emitting element (e.g., an organic light emitting diode) may be increased, so that the luminous efficiency of the light emitting element (e.g., the organic light emitting diode) may be improved.

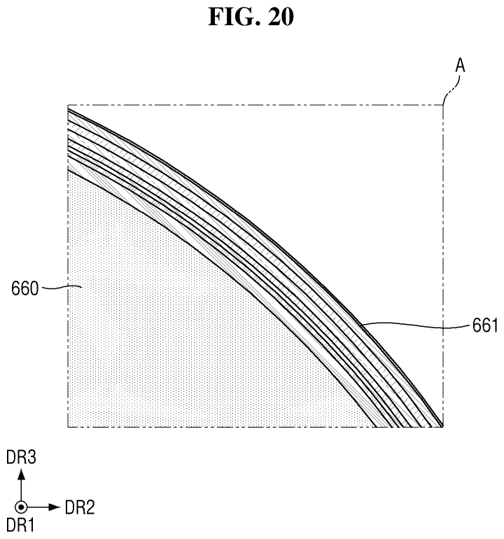

FIG. 19 is a plan view of a filler 660 of a display device 1000 according to one embodiment, and FIG. 20 is an enlarged view of portion A of FIG. 19.

As illustrated in FIGS. 19 and 20, when the filler 660 is deformed by heat, the degree of deformation may be the greatest at the edge of the filler 660. For example, the degree of expansion or contraction may be the greatest at the edge of the filler 660.

According to one embodiment, stress of the light shielding layer 650 due to heat deformation of the filler 660 may be minimized by adjusting the cure rate of the buffer layer 900, the gap 560, and the filler 660.

In those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a filler;
a display panel on the filler;
a window member on the display panel;
a light shielding layer between the window member and the filler; and
a buffer layer between the light shielding layer and the filler.

2. The display device of claim 1,
wherein the light shielding layer and the buffer layer are formed of the same material.

3. The display device of claim 1,
wherein the light shielding layer and the buffer layer have the same color.

4. The display device of claim 1,
wherein the buffer layer contains black dye.

5. The display device of claim 1,
wherein the buffer layer is in contact with the filler and the light shielding layer.

6. The display device of claim 1, further comprising a housing adjacent to the outer surface of the filler.

7. The display device of claim 6,
wherein the housing comprises:
a sidewall adjacent to the outer surface of the filler and the outer surface of the buffer layer; and
a base plate extending from the sidewall.

8. The display device of claim 7,
wherein the sidewall contacts the outer surface of the light shielding layer and the outer surface of the window member.

9. The display device of claim 7, further comprising a first adhesive layer between the base plate and the filler.

10. The display device of claim 1, further comprising a second adhesive layer disposed between the display panel and the light shielding layer and between the display panel and the window member.

11. The display device of claim 10,
wherein the light shielding layer is disposed between the second adhesive layer and the window member in addition to being disposed between the buffer layer and the window member.

12. The display device of claim 11,
wherein the light shielding layer is in contact with the buffer layer and the second adhesive layer.

13. The display device of claim 10,
wherein the second adhesive layer is surrounded by the buffer layer.

14. The display device of claim 10, further comprising a polarization plate between the display panel and the second adhesive layer.

15. The display device of claim 1,
wherein, in plan view, the light shielding layer surrounds a display area of the display panel.

16. The display device of claim 1,
wherein the light shielding layer is disposed between the edge of the window member and the buffer layer.

17. A display device comprising:
a filler;
a display panel on the filler;
a window member on the display panel;
a light shielding layer between the window member and the filler; and
a housing spaced apart from the filler,
wherein at least a portion of the light shielding layer covers a gap between the filler and the housing.

18. The display device of claim 17,
wherein the edge of the light shielding layer is disposed on the gap.

19. The display device of claim 18,
wherein at least a portion of the light shielding layer overlapping the filler is in contact with the filler.

20. The display device of claim 17, further comprising a first adhesive layer between the filler and a base plate of the housing.

21. The display device of claim 20,
wherein the gap is defined by the housing, the first adhesive layer, the filler, and the light shielding layer.

22. The display device of claim 20,
wherein a sidewall of the housing is adjacent to the outer surface of the first adhesive layer and the outer surface of the filler.

23. The display device of claim 20,
wherein a sidewall of the housing is adjacent to the outer surface of the first adhesive layer, the outer surface of the filler, the outer surface of the light shielding layer, and the outer surface of the window member.

24. The display device of claim 23,
wherein the sidewall of the housing is spaced apart from the outer surface of the first adhesive layer and the outer surface of the filler, and
the sidewall of the housing is in contact with the outer surface of the light shielding layer and the outer surface of the window member.

25. The display device of claim 20,
wherein at least a portion of a sidewall of the housing is in contact with the lower surface of the light shielding layer.

26. The display device of claim 25,
wherein a portion of the sidewall of the housing is in further contact with the outer surface of the light shielding layer.

27. A display device comprising:
a filler;
a display panel on the filler;
a window member on the display panel; and
a light shielding layer between the window member and the filler,
wherein the filler has a cure rate of 90%.

28. The display device of claim 27,
wherein the thermal expansion coefficient of the light shielding layer and the thermal expansion coefficient of the filler are the same.

29. The display device of claim 27,
wherein a difference between the thermal expansion coefficient of the light shielding layer and the thermal expansion coefficient of the filler is no more than 10%.

30. The display device of claim 27,
wherein the filler and the light shielding layer are formed of the same material.
